(19) United States
(12) Patent Application Publication
(10) Pub. No.: US 2014/0284559 A1
(43) Pub. Date: Sep. 25, 2014

(54) METHOD OF MANUFACTURING ORGANIC LIGHT-EMITTING DISPLAY APPARATUS, DEPOSITION APPARATUS USING THE METHOD, AND ORGANIC LIGHT-EMITTING DISPLAY APPARATUS MANUFACTURED BY USING THE METHOD

(71) Applicant: Samsung Display Co., Ltd., Yongin- City (KR)

(72) Inventor: Dong-Wook Kim, Yongin-City (KR)

(73) Assignee: Samsung Display Co., Ltd., Yongin City (KR)

(21) Appl. No.: 13/941,424

(22) Filed: Jul. 12, 2013

(30) Foreign Application Priority Data
Mar. 20, 2013 (KR) 10-2013-0029912

(51) Int. Cl. H01L 51/56; H01L 27/32

(52) U.S. Cl. CPC H01L 51/56; H01L 27/3258; H01L 2227/323; H01L 2251/56
USPC 257/40; 438/46

(57) ABSTRACT

A method of manufacturing an organic light-emitting display apparatus, a deposition apparatus using the method, and an organic light-emitting display apparatus manufactured by the method, in which substrate effluence is blocked during transportation of a transport unit. The method includes: rotating a transfer unit, to which a substrate is placed or is to be placed, by first and second flip transport units, in a first rotational direction or in an opposite rotational direction to the first rotational direction, by a set angle; forming a layer by depositing a material emitted from a deposition assembly, on the substrate while placing the deposition assembly and the substrate to be separated from each other by a set distance and moving the substrate relatively with respect to the deposition assembly in a first direction via a first transfer unit; and transporting the transport unit in the opposite direction to the first direction after deposition.

### CROSS-REFERENCE TO RELATED APPLICATION

This application claims priority to and the benefit of Korean Patent Application No. 10-2013-0029912, filed on Mar. 20, 2013, in the Korean Intellectual Property Office, the disclosure of which is incorporated herein in its entirety by reference.

### BACKGROUND

1. Field

The following description relates to a method of manufacturing an organic light-emitting display apparatus, a deposition apparatus using the method, and an organic light-emitting display apparatus manufactured by using the method.

2. Description of the Related Art

Organic light-emitting display apparatuses have wider viewing angles, better contrast characteristics, and faster response speeds than other display apparatuses, and thus have drawn attention as a next-generation display device.

An organic light-emitting display device includes an intermediate layer including an emission layer disposed between a first electrode and a second electrode that face each other. The first and second electrodes and the intermediate layer may be formed using various suitable methods, one of which is an independent deposition method. When an organic light-emitting display device is manufactured by using the deposition method, a fine metal mask (FMM) having substantially the same pattern as that of an intermediate layer to be formed is disposed to closely contact a substrate on which the intermediate layer and the like are formed, and an intermediate layer material is deposited on the FMM to form an intermediate layer having a set or predetermined pattern.

However, according to a deposition method according to the comparable art in which an FMM is used, when a large organic light-emitting display apparatus is manufactured by using a large substrate or a plurality of organic light-emitting display apparatuses are simultaneously manufactured by using a large mother substrate, a large FMM has to be inevitably used, and thus, drooping of the FMM is caused due to the weight of the FMM itself, and an intermediate layer or the like having accurate patterns that are set in advance may not be formed. Moreover, a considerable amount of time is required to align and closely attach the large substrate and the large FMM and then separate them again after the deposition. Thus, the manufacturing time is increased and production efficiency is decreased.

### SUMMARY

Aspects of embodiments of the present invention are directed toward a method of manufacturing an organic light-emitting display apparatus in which effluence (pollution) of a substrate being deposited is blocked or prevented during transportation of a transfer unit, and maintenance of the organic light-emitting display apparatus is easy, a deposition apparatus using the method, and an organic light-emitting display apparatus manufacturing by using the method. However, the aspects and embodiments of the present invention are provided as examples and the scope of the present invention is not limited by the aspects and embodiments of the present invention.

According to an embodiment of the present invention, there is provided a method of manufacturing an organic light-emitting display apparatus, the method comprising: detachably fixing a substrate on a surface of a transfer unit that is disposed at a first flip transport unit; locating the surface of the transfer unit, to which the substrate is fixed, with a first plane, by rotating the first flip transport unit in a second rotational direction by 180 degrees; transporting the transfer unit from the first flip transport unit to a first transport unit; forming a layer by depositing a deposition material emitted from a deposition assembly, on the substrate while placing the deposition assembly and the substrate to be separated from each other by a set or predetermined distance and moving the substrate relatively with respect to the deposition assembly in a first direction via the first transfer unit; transporting the transfer unit from the first transport unit to a second flip transport unit; rotating the second flip transport unit in a first rotational direction that is opposite to the second rotational direction by 180 degrees while the transfer unit, on which the substrate is fixed, is disposed on the second flip transport unit; separating and discharging the substrate from the transfer unit; locating the surface of the transfer unit, to which the substrate is fixed, within a second plane, by rotating the second flip transport unit in the second rotational direction by a first angle, while the transfer unit, from which the substrate is separated, is located on the second flip transport unit; transporting the transfer unit from the second flip transport unit to the second transfer unit; transporting the transfer unit to the first flip transport unit in the opposite direction to the first direction via a second transport unit; and rotating the first flip transport unit in the first rotational direction by the first angle while the transfer unit is disposed on the first flip transport unit.

According to another embodiment of the present invention, there is provided a method of manufacturing an organic light-emitting display apparatus, the method including: detachably fixing a substrate on a surface of a transfer unit disposed at a first flip transport unit; locating the surface of the transfer unit, to which the substrate is fixed, within a first plane, by rotating the first flip transport unit in a second rotational direction by 180 degrees; transporting the transfer unit from the first flip transport unit to a first transport unit; forming a layer by depositing a deposition material emitted from a deposition assembly, on the substrate while placing the deposition assembly and the substrate to be separated from each other by a set distance and moving the substrate relatively with respect to the deposition assembly in a first direction via the first transfer unit; transporting the transfer unit from the first transport unit to a second flip transport unit; rotating the second flip transport unit in a first rotational direction opposite to the second rotational direction by 180 degrees while the transfer unit, on which the substrate is fixed, is disposed on the second flip transport unit; separating and discharging the substrate from the transfer unit; locating the surface of the transfer unit, to which the substrate is fixed, within a second plane, by rotating the second flip transport unit in the first rotational direction by a first angle, while the transfer unit, from which the substrate is separated, is located on the second flip transport unit; transporting the transfer unit from the second flip transport unit to the second transfer unit; transporting the transfer unit to the first flip transport unit in the opposite direction to the first direction via the second transport unit; and rotating the first flip transport unit in the second rotational direction by the first angle while the transfer unit is disposed on the first flip transport unit.

When rotating the first flip transport unit or the second flip transport unit, the first flip transport unit or the second flip transport unit may be rotated with respect to an axis that is parallel to an axis defined by a portion where the first plane and the second plane cross each other.

The first plane and the second plane may cross each other perpendicularly, and the first angle may be 90 degrees.

The locating the surface of the transfer unit, to which the substrate is fixed, within the first plane, by rotating the first flip transport unit in the second rotational direction by 180 degrees may include locating first flip guide rails of the first flip transport unit along the same line as first guide rails of the first transport unit.

The locating the surface of the transfer unit, to which the substrate is fixed, within the second plane, by rotating the second flip transport unit by the first angle, may include locating second flip guide rails of the second flip transport unit along the same line as second guide rails of the second transport unit.

According to another embodiment of the present invention, there is provided an organic light-emitting display apparatus including: a substrate; a plurality of thin film transistors disposed on the substrate; a plurality of pixel electrodes that are electrically connected to the plurality of thin film transistors; a plurality of deposition layers disposed on the plurality of pixel electrodes; and an opposite electrode disposed on the plurality of deposition layers, wherein at least one of the deposition layers is a linear pattern that is formed by utilizing at least one of the above-described methods.

### BRIEF DESCRIPTION OF THE DRAWINGS

The above and other features and advantages of the present invention will become more apparent by describing in detail exemplary embodiments thereof with reference to the attached drawings in which:

FIG. 1 is a conceptual plan view that schematically illustrates a deposition apparatus according to an embodiment of the present invention;

FIG. 2 is a conceptual side view of a portion of the deposition apparatus of FIG. 1 according to an embodiment of the present invention;

FIG. 3 is a schematic perspective view illustrating a portion of a deposition unit of the deposition apparatus of FIG. 1, according to an embodiment of the present invention;

FIG. 4 is a schematic front view illustrating a portion of a deposition unit of the deposition apparatus of FIG. 1, according to an embodiment of the present invention;

FIG. 5 is a schematic perspective view of a first transport unit and a portion of a transfer member of the deposition apparatus of FIG. 3, according to an embodiment of the present invention;

FIG. 6 is a schematic perspective view illustrating a portion of a first flip unit of the deposition apparatus of FIG. 1, according to an embodiment of the present invention; and

FIG. 7 is a schematic cross-sectional view illustrating an organic light-emitting display apparatus manufactured by using the deposition apparatus of FIG. 1, according to an embodiment of the present invention.

### DETAILED DESCRIPTION

As used herein, the term “and/or” includes any and all combinations of one or more of the associated listed items. Expressions such as “at least one of,” when preceding a list of elements, modify the entire list of elements and do not modify the individual elements of the list.

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Also, sizes of elements may be exaggerated or reduced in the drawings for convenience of description. For example, the sizes and thicknesses of elements in the drawings are provided for convenience of description, and thus are not limited as illustrated in the drawings.

Hereinafter, an x-axis, a y-axis, and a z-axis are not limited to three axes of an orthogonal coordinate system but may be construed as a coordinate system including the orthogonal coordinate system. For example, the x-axis, the y-axis, and the z-axis may be orthogonal to one another, or may be crossed by one another but not orthogonal to one another.

It will also be understood that when an element such as a layer, a film, a region, or a plate is referred to as being “on” another element, it can be directly on the other element, or intervening elements may also be present.

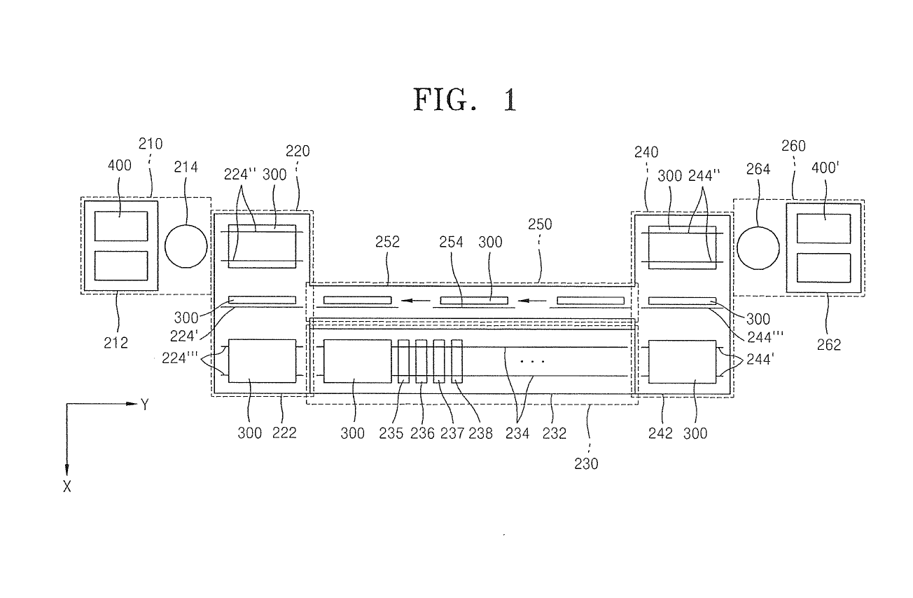

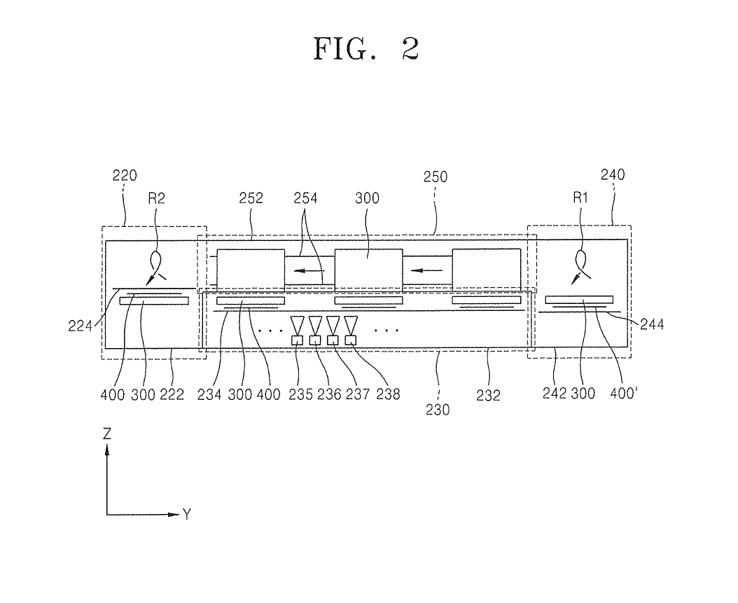

FIG. 1 is a conceptual plan view that schematically illustrates a deposition apparatus according to an embodiment of the present invention. FIG. 2 is a conceptual side view of a portion of the deposition apparatus of FIG. 1 according to an embodiment of the present invention.

Referring to FIGS. 1 and 2, the deposition apparatus includes a loading unit 210, a first flip unit 220, a deposition unit 230, a second flip unit 240, a conveyer unit 250, and an unloading unit 260.

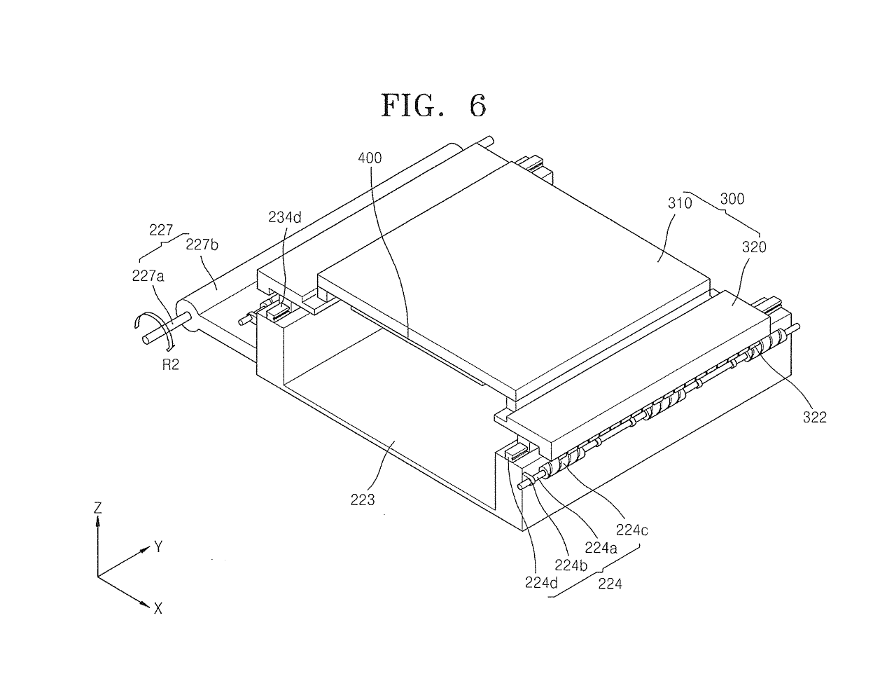

The loading unit 210 may include a first rack 212 and an introduction robot 214. The first flip unit 220 is disposed at a side of the deposition unit 230 and the conveyer unit 250 (in a −Y direction). The first flip unit 220 may include a first flip transport unit 224 (see FIG. 6), which is capable of transporting a transfer unit 300.

In the first rack 212, a plurality of substrates 400 may be loaded before deposition is conducted. The introduction robot 214 holds a substrate 400 loaded in the first rack 212, and a second transport unit 254 of the conveyer unit 250 transports the substrate 400 and places the same in the transfer unit 300 located in the first flip unit 220. The substrate 400 may be fixed to an electrostatic chuck included in the transfer unit 300 via, for example, electrostatic force, or may be fixed to the transfer unit 300 by using a clamp or the like. According to necessity, before fixing the substrate 400 to the transfer unit 300, the substrate 400 may be aligned with the transfer unit 300.

When the substrate 400 is mounted on the transfer unit 300 located in the first flip unit 220, the substrate 400 is mounted on a plane of the transfer unit 300 in a +Z direction (the plane to which the substrate 400 is fixed). Then, the transfer unit 300 on which the substrate 400 is fixed is rotated by 180 degrees with respect to a Y-axis in a first rotational direction R1 so that the substrate 400 fixed to the transfer unit 300 is directed in a −Z direction with respect to the transfer unit 300.

Here, the transfer unit 300 is movably coupled to the first flip transport unit 224 (see FIG. 6) in the first flip unit 220, and accordingly, when the transfer unit 300 rotates, the first flip transport unit 224 also rotates. In more detail, the transfer unit 300 may be able to rotate as the first flip transport unit 224 rotates. The first flip transport unit 224 may include a pair of first flip guide rails, and in this case, a pair of first flip guide rails may be included in the first flip unit 220. In FIG. 1, three pairs of first flip guide rails are illustrated as included in the first flip unit 220 of FIG. 1 for convenience in order to mark positions at which the one pair of first flip guide rails may be located.

That is, when the transfer unit 300 is transported from the conveyer unit 250 to the first flip unit 220, the transfer unit 300 is transported such that a plane thereof on which the substrate 400 is to be fixed is perpendicular to an XY plane. Accordingly, the transfer unit 300 is transported and then coupled to the first flip transport unit 224 denoted as 224′ while one of the two first flip guide rails is located above the other in the +Z direction.

In this state, the first flip transport unit 224 and the transfer unit 300 are rotated in the first rotational direction R1 (−X direction) by 90 degrees with respect to the Y-axis, so that the plane of the transfer unit 300 on which the substrate 400 is fixed is parallel to the XY plane, and the first flip transport unit 224 is located above the transfer unit 300 as denoted by the reference numeral 224″. In this state, the substrate 400 is placed and fixed on the plane of the transfer unit 300, which is in the +Z direction, and then, the first flip transport unit 224 and the transfer unit 300 are rotated in a second rotational direction R2, which is an opposite direction to the first rotational direction R1, by 180 degrees with respect to the Y-axis so that the substrate 400 is located in the −Z direction with respect to the transfer unit 300, and the first flip transport unit 224 is located below the transfer unit 300 as denoted by a reference numeral 224″. In this state, the first flip transport unit 224 transports the transfer unit 300, on which the substrate 400 is fixed, to the deposition unit 230.

As illustrated in FIGS. 1 and 2, the deposition unit 230 includes a chamber 232, and a plurality of deposition assemblies 235, 236, 237, and 238 and a first transport unit 234 may be disposed in the chamber 232. While four deposition assemblies 235, 236, 237, and 238 disposed in the chamber 232 are illustrated, the number of deposition assemblies may vary according to deposition materials and deposition conditions.

The chamber 232 of the deposition unit 230 may be maintained in a vacuum state or a near vacuum state while deposition is being performed. Accordingly, a gate valve may be disposed between a chamber 222 of the first flip unit 220 and the chamber 232 of the deposition unit 230, and a buffer chamber may be interposed between the chamber 222 of the first flip unit 220 and the chamber 232 of the deposition unit 230 according to necessity.

The first transport unit 234 transports the transfer unit 300, to which the substrate 400 is detachably fixed, in the first direction (+Y direction) such that a surface of the transfer unit 300, to which the substrate 400 is fixed, is located within a first plane. While the first transport unit 234 transports the transfer unit 300, to which the substrate 400 is fixed, the deposition assemblies 235, 236, 237, and 238 are each spaced apart from the substrate 400 by a set or predetermined distance to deposit a material on the substrate 400. The first transport unit 234 may include a pair of first guide rails 234d that extend in the first direction (+Y direction).

When the first flip transport unit 224 transports the transfer unit 300, to which the substrate 400 is fixed, to the deposition unit 230, the first flip guide rails of the first flip transport unit 224 may be located along the same line as the first guide rails 234d of the first transport unit 234.

The second flip unit 240 may be located at the other side of the deposition unit 230 and the conveyer unit 250 (in the +Y direction). The second flip unit 240 may include a second flip transport unit, which is capable of transporting the transfer unit 300. A gate valve may be disposed between a chamber 242 of the second flip unit 240 and the chamber 232 of the deposition unit 230, and according to necessity, a buffer chamber may be interposed between the chamber 242 of the second flip unit 240 and the chamber 232 of the deposition unit 230. The unloading unit 260 may include a second rack 262 and a withdrawal robot 264.

When the deposition unit 230 completes deposition on the substrate 400, thus denoted as 400′, so that the transfer unit 300, to which the substrate 400′ is fixed, is transferred from the first transport unit 234 of the deposition unit 230 to the second flip transport unit of the second flip unit 240, the substrate 400′ is located in the −Z direction with respect to the transfer unit 300, and the second flip transport unit 244 is located below the transfer unit 300 as denoted by a reference numeral 244′. Then, the transfer unit 300, to which the substrate 400′ is fixed, rotates in the first rotational direction R1 with respect to the Y-axis so that the substrate 400′ fixed to the transfer unit 300 is directed in the +Z direction with respect to the transfer unit 300.

Here, the transfer unit 300 is movably coupled to the second flip transport unit in the second flip unit 240, and accordingly, when the transfer unit 300 rotates, the second flip transport unit also rotates. In detail, the transfer unit 300 is able to rotate as the second flip transport unit rotates. The second flip transport unit may include a pair of second flip guide rails, and in this case, a pair of second flip guide rails may be included in the second flip unit 240. In FIG. 1, three pairs of second flip guide rails are included in the second flip unit 240 for convenience in illustrating possible positions of the one pair of second flip guide rails according to rotation.

That is, while the substrate 400′ is located in the −Z direction with respect to the transfer unit 300 and the second flip transport unit is located below the transfer unit 300 as denoted by a reference numeral 244′, the second flip transport unit and the transfer unit 300 rotate in the first rotational direction R1 (−X direction) with respect to the Y-axis, so that the substrate 400′ is located in the +Z direction with respect to the transfer unit 300 and the second flip transport unit is located above the transfer unit 300 as denoted by a reference numeral 244″. In this state, the withdrawal robot 264 is located in the +Z direction of the transfer unit 300 to take out the substrate 400′ that is separated from the transfer unit 300 and to load the substrate 400′ in the second rack 262.

Then, the transfer unit 300, from which the substrate 400′ is separated, is rotated with respect to the Y-axis in the second rotational direction R2 by 90 degrees, so that a surface of the transfer unit 300, on which the substrate 400′ is fixed, is perpendicular to the XY plane, and the second flip transport unit, to which the transfer unit 300 is movably coupled, is also located as denoted by a reference numeral 244′″. If the second flip transport unit includes a pair of second flip guide rails, one of the two second flip guide rails is located above the other in the +Z direction. In this state, the second flip transport unit transports the transfer unit 300 to the conveyer unit 250.

The conveyer unit 250 includes the second transport unit 254, and the second transport unit 254 transports the transfer unit 300, from which the substrate 400′ is separated, in an opposite direction to the first direction (+Y direction), that is, from the second flip unit 240 to the first flip unit 220. Consequently, the transfer unit 300 may be circularly transported via the first transport unit 234 and the second transport unit 254. The second transport unit 254 transports the transfer unit 300 to the first flip unit 220 such that a surface of the transfer unit 300, to which the substrate 400 is fixed, is perpendicular to the XY plane. That is, the second transport unit 254 may include a pair of second guide rails that extend in the first direction (+Y direction), and in this case, one of the two second guide rails may be disposed above the other (in the +Z direction).

When the second flip transport unit transports the transfer unit 300, from which the substrate 400′ is separated, from the second flip unit 240 to the conveyer unit 250, the second flip guide rails of the second flip transport unit may be located along the same line as the second guide rails of the second transport unit 254 of the conveyer unit 250.

The chamber 222 of the first flip unit 220, the chamber 242 of the second flip unit 240, and the chamber 252 of the conveyer unit 250 are ones in which no deposition is performed and are for transporting or rotating the transfer unit 300. Accordingly, no gate valve or buffer chamber is interposed between these chambers, thereby simplifying the structure of the deposition apparatus, and if necessary, the chambers 222, 242 and/or 252 may be integrally formed.

According to the deposition apparatus of the current embodiment of the present invention, when the substrate 400′ is separated from the transfer unit 300 and the transfer unit 300 is returned from the second flip unit 240 to the first flip unit 220, the transfer unit 300 is returned such that a surface of the transfer unit 300, on which the substrate 400′ is fixed, is perpendicular to the XY plane. Accordingly, a surface area for the deposition apparatus may be significantly reduced compared to an embodiment where the transfer unit 300 is returned such that the surface of the transfer unit 300, to which the substrate 400 is fixed, is parallel to the XY plane.

Alternatively, reducing a surface area of the deposition apparatus may also be considered by returning the transfer unit 300 such that a surface of the transfer unit 300, to which the substrate 400′ is fixed, is parallel to the XY plane in an upper portion of the deposition unit 230 after the substrate 400′ is separated from the transfer unit 300. However, a material may also attach to the transfer unit 300 when the deposition unit 230 deposits the material on the substrate 400, and accordingly, when the transfer unit 300 is returned with the surface thereof, to which the substrate 400 is fixed, being parallel to the XY plane, defects may be generated as the material that is previously attached on the transfer unit 300 drops to the deposition unit 230.

However, according to the deposition apparatus of the current embodiment of the present invention as described above, the transfer unit 300 is returned such that the surface thereof, to which the substrate 400 is fixed, is perpendicular to the XY plane, and thus, the transfer unit 300 is returned not along a path above the deposition unit 230 but along a lateral side of the deposition unit 230 (−X direction). Accordingly, when the transfer unit 300 is returned, even if the material that is previously attached to the transfer unit 300 drops, an influence of the material on the deposition unit 230 may be effectively prevented.

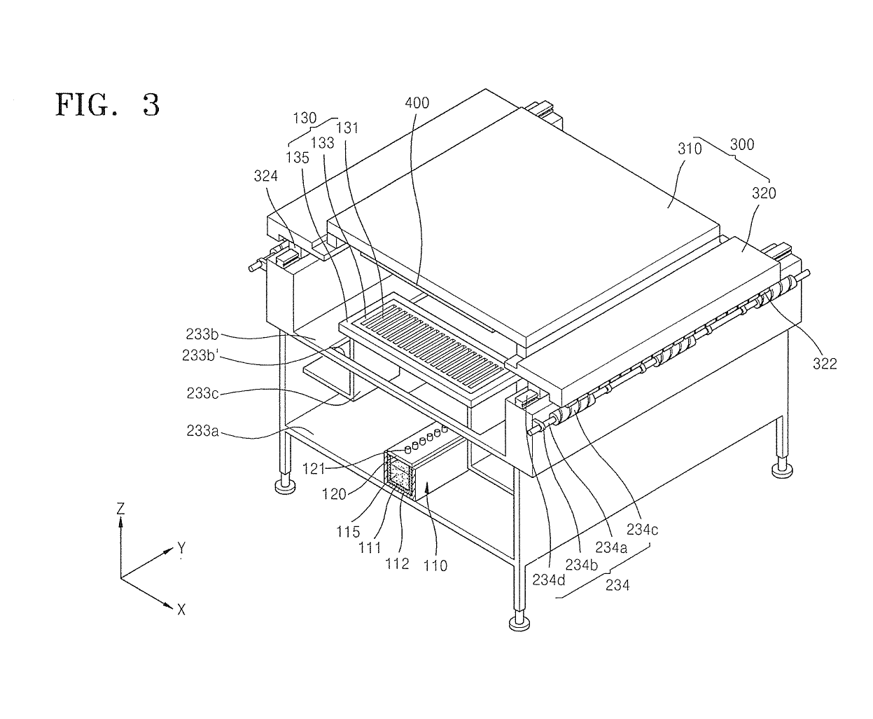

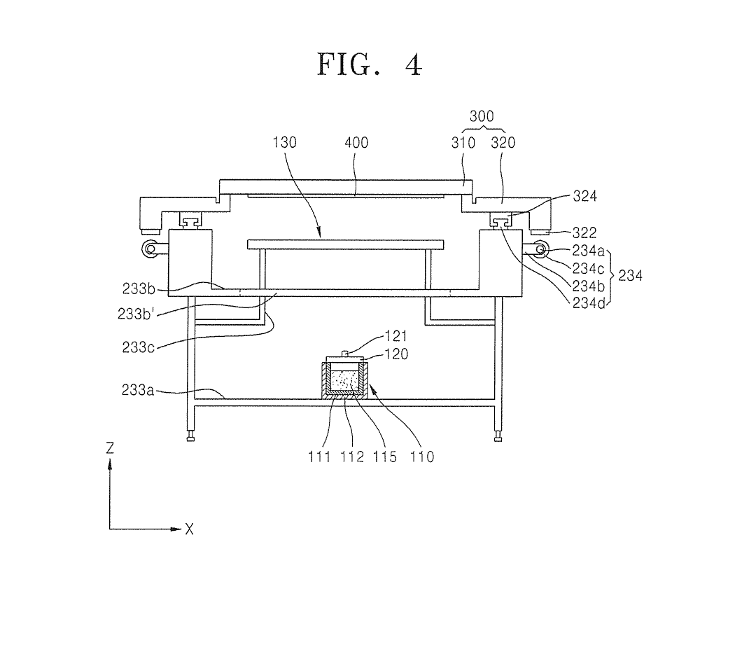

FIG. 3 is a schematic perspective view illustrating a portion of the deposition unit 230 of the deposition apparatus of FIG. 1, according to an embodiment of the present invention. FIG. 4 is a schematic front view illustrating a portion of the deposition unit 230 of the deposition apparatus of FIG. 1, according to an embodiment of the present invention. Referring to FIGS. 3 and 4, the deposition unit 230 according to the current embodiment of the present invention includes the first transport unit 234 and at least one deposition assembly as described above. The at least one deposition assembly is separated from the substrate 400 by a set or predetermined distance while the first transport unit 234 transports the transfer unit 300, to which the substrate 400 is fixed, in a first direction (+Y direction) and deposits a material on the substrate 400.

The deposition assembly may include a deposition source 110, a deposition source nozzle unit 120, a patterning slit sheet 130, or the like. According to necessity, a stage for adjusting a position of the patterning slit sheet 130, a camera for identifying whether the patterning slit sheet 130 and the substrate 400 are aligned, and a sensor for measuring an interval between the patterning slit sheet 130 and the substrate 400 may be further included.

The deposition source 110 may emit a deposition material 115. The deposition assembly may include at least one deposition source 110. The deposition source 110 may be disposed at a lower portion of the deposition apparatus to emit a deposition material 115 toward the substrate 400 (e.g., +Z direction) as the deposition material 115 inside the deposition source 110 is sublimed or gasified. In more detail, the deposition source 110 may include a crucible 111 in which the deposition material 115 is filled and a heater that heats the crucible 111 to evaporate the deposition material 115 filled in the crucible 111.

In a direction towards the first transport unit 234 of the deposition source 110 (+Z direction), that is, in a direction to the substrate 400, the deposition source nozzle unit 120, in which a plurality of deposition source nozzles 121 are formed, is disposed. Referring to FIG. 3, the deposition source nozzle unit 120 includes the plurality of deposition source nozzles 121. The deposition source nozzles 121 may protrude from the deposition source 110 towards the substrate 400 or may simply have the form of a planar hole formed in the deposition source nozzle unit 120.

Referring to FIG. 3, the deposition source nozzle unit 120 includes the plurality of deposition source nozzles 121 arranged in the first direction (+Y direction), but embodiments of the present invention are not limited thereto. For example, the deposition source nozzle unit 120 may also include a plurality of deposition source nozzles that are arranged across the first direction (+Y direction) in an approximately parallel direction to the substrate 400 (X direction).

The patterning slit sheet 130 may be disposed to face the deposition source nozzle unit 120, for example, may have a structure in which a plurality of patterning slits are formed in a set or predetermined direction (X-axis direction). The patterning slit sheet 130 is disposed between the deposition source 110 and the substrate 400. The deposition material 115 that is gasified in the deposition source 110 passes through the deposition source nozzle unit 120 and the patterning slit sheet 130 to be deposited on the substrate 400. If a uniform deposition layer is to be formed on the entire surface of the substrate 400, the patterning slit sheet 130 may have openings that extend along an X-axis, instead of a plurality of patterning slits.

The patterning slit sheet 130 may be formed using the same method as a method such as etching that is used to form an FMM, in particular, a stripe-type mask. The patterning slit sheet 130 may be separated from the deposition source 110 (and the deposition source nozzle unit 120 coupled thereto) by a set or predetermined distance.

So that the deposition material 115 that is discharged from the deposition source 110 passes through the deposition source nozzle unit 120 and the patterning slit sheet 130 to be deposited on the substrate 400 in a desired pattern, the chamber 232 of the deposition unit 230 has to basically be maintained in high vacuum in substantially the same manner as FMM deposition. Also, a temperature of the patterning slit sheet 130 has to be sufficiently lower than a temperature of the deposition source 110 (about 100° C. or lower). Thermal expansion of the patterning slit sheet 130 may be reduced or minimized only when the temperature of the patterning slit sheet 130 is sufficiently low. In other words, if the temperature of the patterning slit sheet 130 increases, the sizes or positions of patterning slits of the patterning slit sheet 130 may deform due to thermal expansion, and thus, the deposition material 115 may be deposited on the substrate 400 in different patterns from the ones set in advance.

The substrate 400, which is fixed to the transfer unit 300, is transported in the first direction (+Y direction) via the first transport unit 234. The substrate 400 may be a substrate for a flat panel display apparatus, and may be, for example, a large substrate, such as a mother glass, from which a plurality of flat panel display apparatuses may be formed.

As described above, according to the deposition method in which an FMM is used, the surface area of the FMM has to be the same as a surface area of the substrate 400. Accordingly, as the size of the substrate 400 increases, the FMM also has to be larger, and this makes it difficult to manufacture the FMM and causes a mask to droop due to its own weight, and thus, an intermediate layer having an exact pattern as set in advance may not be formed.

However, according to the deposition apparatus of the current embodiment of the present invention, deposition is performed as the deposition assembly and the substrate 400 move relatively with respect to each other. In more detail, while the first transport unit 234 transports the substrate 400 fixed to the transfer unit 300 in the first direction (+Y direction), the deposition assembly that is separated from the substrate 400 by a set or predetermined distance deposits a material on the substrate 400. In other words, as the substrate 400 that is disposed to face the deposition assembly is transported in the first direction (+Y direction), deposition is performed in a scanning manner. While FIG. 3 illustrates that deposition is performed as the substrate 400 moves in the +Y direction, the embodiments of the present invention are not limited thereto. For example, alternatively, while the position of the substrate 400 is fixed, the deposition assembly may perform deposition while moving in the −Y direction, or other various deposition methods may be performed.

Accordingly, according to the deposition apparatus of the current embodiment of the present invention, a size of the patterning slit sheet 130 may be significantly smaller than a size of an FMM according to the comparable art. That is, according to the deposition apparatus of the current embodiment of the present invention, as the substrate 400 moves along the Y-axis direction, deposition is performed continuously, that is, in a scanning manner, and thus, deposition may be sufficiently conducted on most portions of the entire surface of the substrate 400 even if a length of the patterning slit sheet 130 in the Y-axis direction may be far smaller than a length thereof in the same directions.

As such, as the size of the patterning slit sheet 130 may be far smaller than the size of the FMM according to the comparable art, it is easy to manufacture the patterning slit sheet 130. That is, in an etching operation for manufacturing the patterning slit sheet 130 or in each subsequent operation, such as a precision tensioning operation, a welding operation, a moving operation, or a washing operation, the patterning slit sheet 130 having a small size is more advantageous over operations related to a large surface FMM. This advantage increases more as a size of a display apparatus increases.

As described above, while the first transport unit 234 transports the substrate 400 fixed to the transfer unit 300 in the first direction (+Y direction), the deposition assembly deposits a material on the substrate 400 while being separated from the substrate 400 by a set distance, which means that the patterning slit sheet 130 is separated from the substrate 400 by a set distance. According to the deposition apparatus using an FMM according to the comparable art, the FMM and the substrate 400 contact each other so that defects are caused accordingly. However, according to embodiment of the present invention, this problem may be effectively prevented, and also, the time for closely adhering the substrate 400 and a mask in an operation is unnecessary, and thus, the manufacturing speed may be significantly increased.

The first transport unit 234 of the deposition unit 230 and the deposition assembly may be supported by a frame, as illustrated in FIGS. 3 and 4. The frame may include a lower frame 233a and an upper frame 233b. The deposition source 110 may be disposed on the lower frame 233a, and the first transport unit 234 may be disposed on the upper frame 233b. The lower frame 233a and the upper frame 233b may be separate members and be coupled to each other, or may be originally formed as a single portion.

A sheet supporting portion 233c for supporting the patterning slit sheet 130 may be disposed on the lower frame 233a. It should be apparent that various modifications may be made such that a stage for controlling a position of the patterning slit sheet 130 may replace the sheet supporting portion 233c or the stage may be interposed between the sheet supporting portion 233c and the patterning slit sheet 130. In addition, an opening 233b′ may be formed in the upper frame 233b such that a material that is evaporated in the deposition source 110 may pass through the patterning slit sheet 130 to be deposited on the substrate 400.

The first transport unit 234 may be disposed on the upper frame 233b, and the transfer unit 300 may be transported in the first direction (+Y direction) via the first transport unit 234.

As illustrated in FIGS. 3 and 4, the transfer unit 300 may include an electrostatic chuck 310, a chuck supporting portion 320 supporting the electrostatic chuck 310, and a first magnetic force generating unit 322 and a guide block 324 disposed at the chuck supporting portion 320. The electrostatic chuck 310 may include a main body formed of ceramic and an electrode that is buried in the main body and to which power is applied; as a high voltage is applied to the electrode, an electrostatic force is generated on a surface of the main body so as to attach the substrate 400 to the transfer unit 300. The first magnetic force generating unit 322 may be disposed on the chuck supporting portion 320, and the transfer unit 300 may be transported along the first guide rails 234d of the first transport unit 234 by a magnetic force generated by the first magnetic force generating unit 322 and the second magnetic force generating unit 234c of the first transport unit 234. The guide block 324 may be movably coupled to the first guide rail 234d so as to prevent the transfer unit 300 from detaching from the first guide rail 234d.

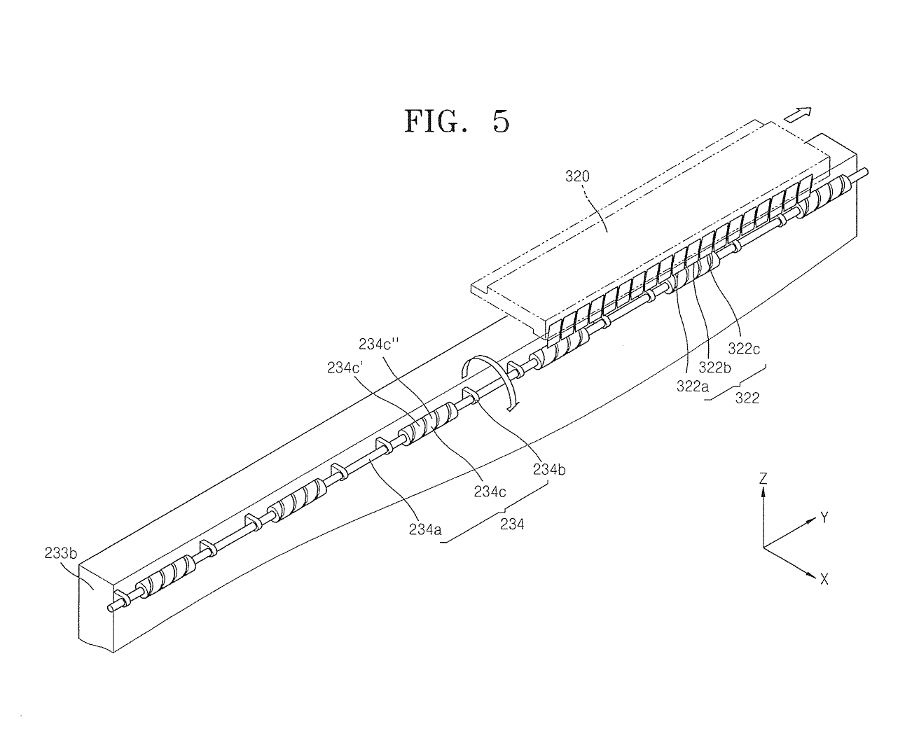

FIG. 5 is a schematic perspective view of the first transport unit 234 and a portion of the transfer unit 300 of the deposition apparatus of FIG. 3. As illustrated in FIG. 5, the first transport unit 234 may include a shaft 234a, a shaft fixing portion 234b that fixes the shaft 234a to the upper frame 233b, a second magnetic force generating unit 234c including a plurality of magnet rollers that are disposed at the shaft 234a, and the first guide rail 234d. The transfer unit 300 may include, as illustrated in FIG. 5, a first magnetic force generating unit 322 that is disposed at the chuck supporting portion 320.

The second magnetic force generating unit 234c is formed of a magnet roller which includes a plurality of magnets 234c′ and 234c″ that are twisted in a spiral form. The magnets 234c′ and 234c″ are twisted with respect to each other around an axis parallel to a transport direction of the transfer unit 300 (+Y direction). The magnets 234c′ and 234c″ that are adjacent to each other may have different polarities. That is, if the magnet 234c′ has an N-pole in an outward direction, the magnet 234c″ adjacent to the magnet 234c′ may include an S-pole in an outward direction.

The shaft 234a connects the plurality of magnet rollers of the second magnetic force generating unit 234c. That is, the plurality of magnet rollers are separated from one another in the transfer direction of the transfer unit 300 (+Y direction), and the shaft 234a connects the plurality of magnet rollers. The shaft 234a transfers a driving force of a driving unit to the magnet rollers.

The shaft fixing portion 234b allows the shaft 234a to be fixed to the upper frame 233b. A through hole is formed in the shaft fixing portion 234b, and the shaft 234a may pass through the through hole and rotate in the through hole.

The first magnetic force generating unit 322 disposed at the chuck supporting portion 320 of the transfer unit 300 may be disposed to correspond to at least one of the plurality of magnet rollers of the second magnetic force generating unit 234c of the first transport unit 234; the first magnetic force generating unit 322 may include a plurality of magnets 322a, 322b, and 322c that are arranged in a series in the first direction (+Y direction) along which the transfer unit 300 is transported. The plurality of magnets 322a, 322b, and 322c are adjacently arranged with different polarities. That is, if the magnet 322a has an N-pole toward the second magnetic force generating unit 234c, the magnet 322b adjacent to the magnet 322a has an S-pole toward the second magnetic force generating unit 234c. Also, the magnet 322c adjacent to the magnet 322b has an N-pole toward the second magnetic force generating unit 234c. As described above, the first magnetic force generating unit 322 may include the plurality of magnets 322a, 322b, and 322c that are arranged such that an N-pole and an S-pole are alternately arranged. The plurality of magnets 322a, 322b, and 322c may include an electromagnet, a permanent magnet, and/or a superconductive magnet.

As such, by using the magnetic force formed by the first magnetic force generating unit 322 disposed at the chuck supporting portion 320 of the transfer unit 300 and the second magnetic force generating unit 234c of the first transport unit 234 adjacent to the first magnetic force generating unit 322, the transfer unit 300 may be transported along the first guide rail 234d of the first transport unit 234. In more detail, as the shaft 234a of the first transport unit 234 rotates, the second magnetic force generating unit 234c having a form in which the magnets 234c′ and 234c″ are twistly rotated, and a repulsive force is further generated between the second magnetic force generating unit 234c and the first magnetic force generating unit 322 according to the rotation, thereby transporting the transfer unit 300 in the first direction (+Y direction).

It should be apparent that the structure of the first transport unit 234 is provided as an example and the embodiments of the present invention are not limited thereto. For example, the first transport unit 234 may have a rail that extends in the first direction (+Y direction), and the transfer unit 300 may include rollers that are disposed on two sides of the rail and are capable of active rotation so that the rail is interposed between the rollers. Accordingly, the transfer unit 300 may move along the rail. As such, the structure of the first transport unit 234 may be suitably modified.

FIG. 6 is a schematic perspective view illustrating a portion of the first flip unit 220 of the deposition apparatus of FIG. 1, according to an embodiment of the present invention. As illustrated in FIG. 6, the first flip unit 220 includes a flip frame 223 and a first flip transport unit 224 disposed on the flip frame 223. The first flip transport unit 224 may be rotated by a first actuator 227, and as illustrated in FIG. 6, as a rotation supporting portion 227b connected to the flip frame 223 rotates with respect to a rotation axis 227a that extends in the first direction (+Y direction), the first flip transport unit 224 may rotate.

Here, when assuming a plane, along which the surface of the transfer unit 300, to which the substrate 400 is fixed, is included, when the first transport unit 234 of the deposition unit 230 transfers the transfer unit 300, as a first plane, and assuming a plane, along which the surface of the transfer unit 300, to which the substrate 400 is fixed, is included, when the second transport unit 254 of the conveyer unit 250 transfers the transfer unit 300, as a second plane, the rotation axis 227a may be parallel to an axis defined by a portion where the first plane and the second plane cross each other.

The first flip transport unit 224 may have substantially the same structure as the first transport unit 234 of the deposition unit 230. That is, the first flip transport unit 224 may include a shaft 224a, a shaft fixing portion 224b that fixes the shaft 224a to the flip frame 223, a plurality of magnet rollers 224c that are arranged on the shaft 224a, and a first flip guide rail 224d.

The guide block 324 of the transfer unit 300 may be movably coupled to the first flip guide rail 224d. Here, in order to prevent the transfer unit 300 from detaching from the first flip transport unit 224 when the first flip transport unit 224 rotates, the first flip guide rail 224d may have a curved portion, as illustrated in FIGS. 3 and 4, which is engaged with a curved portion of the guide block 324, thereby preventing detachment of the transfer unit 300.

The curved portion of the first flip guide rail 224d may be formed, for example, as illustrated in FIG. 6, by forming grooves in two lateral surfaces of the first flip guide rails 224d in the first direction (+Y direction), and the guide block 324 may include a curved portion that is formed as a protrusion to be inserted into the grooves is formed in the guide block 324. Not only the first flip guide rail 224d but also the first guide rail 234d of the first transport unit 234, a second guide rail of the second transport unit 254, and a second flip guide rail of the second flip transport unit may have a curved portion as described above.

The second flip transport unit of the second flip unit 240 may have a similar configuration as the first flip transport unit 224. That is, the second flip unit 240 may include a second actuator that may rotate the second flip transport unit.

Described above is an embodiment in which the transfer unit 300 is transferred from the conveyer unit 250 to the first flip unit 220 such that the surface of the transfer unit 300, to which the substrate 400 is fixed, is perpendicular to the XY plane. That is, the first plane, along which the surface of the transfer unit 300, to which the substrate 400 is fixed, is included, when the first transport unit 234 of the deposition unit 230 transfers the transfer unit 300, and the second plane, along which the surface of the transfer unit 300, to which the substrate 400 is fixed, is included, when the second transport unit 254 of the conveyer unit 250 transfers the transfer unit 300, cross each other perpendicularly. However, the embodiments of the present invention are not limited thereto. That is, when the transfer unit 300 is transferred from the conveyer unit 250 to the first flip unit 220, the transfer unit 300 may also be transported such that the surface thereof (to which the substrate 400 is fixed) is disposed at a previously set angle (first angle) instead of being perpendicular to the XY plane.

In this case, the first flip transport unit 224 and the transfer unit 300 are rotated with respect to the Y-axis in the first rotational direction R1 (−X direction) by the first angle, so that the surface of the transfer unit 300, to which the substrate 400 is fixed, is parallel to the XY plane, and also, the surface of the transfer unit 300, to which the substrate 400 is fixed, may be disposed in a +Z direction.

Similarly, after the deposition unit 230 completes deposition on the substrate 400, when the transfer unit 300 is transported to the second flip transport unit of the second flip unit 240 via the first transport unit 234, the second flip transport unit rotates in the first rotational direction R1 by 180 degrees together with the transfer unit 300, and when the substrate 400′ is separated from the transfer unit 300, the second flip transport unit may be rotated in the second rotational direction R2 not by 90 degrees but by the first angle.

While described above is an embodiment (a first case) in which after the deposition unit 230 completes deposition on the substrate 400, the second flip unit 240 rotates the transfer unit 300 in the first rotational direction R1 by 180 degrees and separates and discharges the substrate 400′ from the transfer unit 300, and then the transfer unit 300 is rotated in the second rotational direction R2, which is an opposite direction to the first rotational direction R1, by the first angle, the embodiments of the present invention are not limited thereto. For example, according to a deposition apparatus according to another embodiment of the present invention (a second case), after separating and discharging the substrate 400′ from the transfer unit 300, the transfer unit 300 may be rotated in the first rotational direction R1 by the first angle, instead of the second rotational direction R2.

If the first angle is 90 degrees, in either of the first and second cases, the transfer unit 300 is transferred to the conveyer unit 250 while being perpendicular to the XY plane. In the first case, as illustrated in FIG. 2, a position of the transfer unit 300 when it is transported from the conveyer unit 250 is higher than a position of the transfer unit 300 when it is transported from the deposition unit 230; however, in the second case, when transported from the conveyer unit 250, the position of the transfer unit 300 is lower than the position of the transfer unit 300 when transported from the deposition unit 230. Accordingly, in the second case, the overall height of the deposition apparatus may be decreased so that installation and maintenance of the deposition apparatus may be easy.

In the second case, the first flip transport unit 224 is rotated, together with the transfer unit 300, in the second rotational direction R2 by the first angle after the transfer unit 300 is transported from the second transport unit 254 of the conveyer unit 250, and when the substrate 400 is fixed to the transfer unit 300, the first flip transport unit 224 is rotated in the second rotational direction R2 by 180 degrees so that the surface thereof, to which the transfer unit 300 is fixed, may be located within the first plane (XY plane).

While the description focuses on the deposition apparatus, the embodiments of the present invention are not limited thereto. For example, a method of manufacturing an organic light-emitting display apparatus by using the deposition apparatus may also be deemed as an embodiment of the present invention.

According to the method of manufacturing an organic light-emitting display apparatus, according to an embodiment of the present invention, the substrate 400 is detachably fixed to a surface of the transfer unit 300 located in the first flip transport unit 224, and then the first flip transport unit 224 is rotated in the second rotational direction R2 by 180 degrees while the substrate 400 is fixed to the transfer unit 300 such that the surface of the transfer unit 300, to which the substrate 400 is fixed, is located in the first plane (which is parallel to the XY plane). Then, the transfer unit 300 is transported from the first flip transport unit 224 to the first transport unit 234 of the deposition unit 230 such that the surface of the transfer unit 300, to which the substrate 400 is fixed, is located within the first plane, and the substrate 400 is transported relatively with respect to a deposition assembly in the first direction (+Y direction) via the first transport unit 234 while the deposition assembly and the substrate 400 are separated apart by a set distance, and a deposition material emitted from the deposition assembly is deposited on the substrate 400 to thereby form a layer.

After deposition is completed, the transfer unit 300 is transported from the first transport unit 234 to the second flip transport unit while the surface of the transfer unit 300, to which the substrate 400 is fixed, is located within the first plane. Next, while the transfer unit 300, to which the substrate 400′ is fixed, is located on the second flip transport unit, the second flip transport unit is rotated in the first rotational direction R1, which is an opposite direction to the second rotational direction R2, by 180 degrees, and then, the substrate 400′ is separated and discharged from the transfer unit 300. Next, while the transfer unit 300 is located on the second flip transport unit, the second flip transport unit is rotated in the second rotational direction R2 by the first angle so as to locate the surface of the transfer unit 300, to which the substrate 400 is fixed, within the second plane.

Next, while the surface of the transfer unit 300, to which the substrate 400 is fixed, is located within the second plane, the transfer unit 300 is transported from the second flip transport unit to the second transport unit 254. Then, in this state, the transfer unit 300 is transported in the opposite direction to the first direction (+Y direction) via the second transport unit 254, thereby transporting the first flip transport unit 224. The first flip transport unit 224 may rotate therebefore in the first rotational direction R1 by a difference between 180 degrees and the first angle, so that the transfer unit 300 may be transported.

When the transfer unit 300 is located on the first flip transport unit 224 after the above-described operations; the first flip transport unit 224 is rotated in the first rotational direction R1 by the first angle so that another new substrate 400 is supplied on the transfer unit 300 and is fixed thereto.

According to a method of manufacturing an organic light-emitting display apparatus, according to another embodiment of the present invention, a rotational direction that is different from the rotational direction described in the method of manufacturing an organic light-emitting display apparatus of the above embodiments may be set.

That is, while the surface of the transfer unit 300, to which the substrate 400′ is fixed, is located on the second flip transport unit, the second flip transport unit is rotated in the first rotational direction R1, which is the opposite direction to the second rotational direction R2, and then, the substrate 400′ is separated and discharged from the transfer unit 300. Next, while the transfer unit 300 is located on the second flip transport unit, the second flip transport unit is rotated in the first rotational direction R1, instead of the second rotational direction R2, by the first angle so as to locate the surface of the transfer unit 300, to which the substrate 400 is fixed, within the second plane. In this case, after transferring the transfer unit 300 in the opposite direction to the first direction (+Y direction) to the first flip transport unit 224 via the second transport unit 254, while the transfer unit 300 is located on the first flip transport unit 224, the first flip transport unit 224 may also be rotated in the second rotational direction R2, instead of the first rotational direction R1, by the first angle, so that another substrate 400 may be supplied onto the transfer unit 300 and fixed thereto.

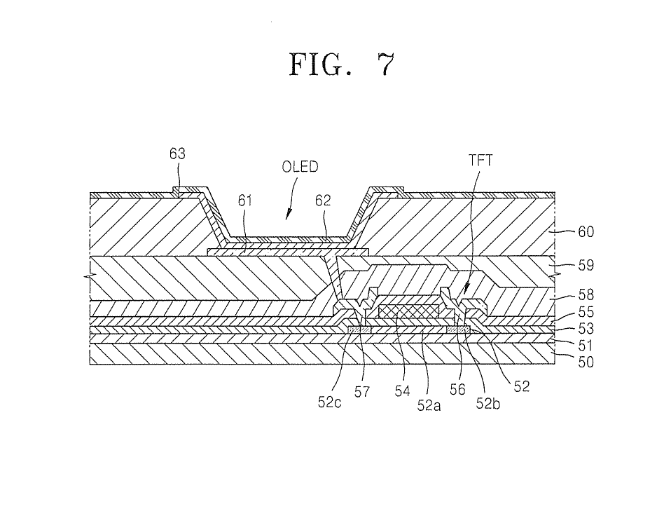

FIG. 7 is a schematic cross-sectional view illustrating an organic light-emitting display apparatus manufactured by using the deposition apparatus of FIG. 1, according to an embodiment of the present invention.

Referring to FIG. 7, various elements of the organic light-emitting display apparatus are formed on a substrate 50. The substrate 50 may be the substrate 400 described above with reference to FIG. 3 or the like, or may be a cut portion of the substrate 400. The substrate 50 may be formed of a transparent material, for example, glass, plastic, or metal.

Common layers, such as a buffer layer 51, a gate insulating layer 53, and an interlayer insulating layer 55, may be formed on the entire surface of the substrate 50, and a patterned semiconductor layer 52, including a channel area 52a, a source contact area 52b, and a drain contact area 52c, may also be formed, and together with the patterned semiconductor layer 52, a gate electrode 54, a source electrode 56, and a drain electrode 57, which are elements of a thin film transistor (TFT), may be formed.

Also, a protection layer 58 covering the TFT and a planarization layer 59 that is formed on the protection layer 58 and has an approximately planar upper surface may be formed on the entire surface of the substrate 50. An organic light-emitting display device (OLED) may be disposed on the planarization layer 59, wherein the OLED includes a patterned pixel electrode 61, an opposite electrode 63 approximately corresponding to the entire surface of the substrate 50, and a multi-layered intermediate layer 62 that is interposed between the pixel electrode 61 and the opposite electrode 63 and includes an emissive layer. Unlike as illustrated in FIG. 7, some layers of the intermediate layer 62 may also be common layers that approximately correspond to the entire surface of the substrate 50, and other layers may be patterned layers that correspond to the pixel electrode 61. The pixel electrode 61 may be electrically connected to the TFT via a via hole. A pixel define layer 60 that covers an edge of the pixel electrode 61 and has an opening that defines each pixel area may be formed on the planarization layer 59 so as to approximately correspond to the entire surface of the substrate 50.

In regard to the organic light-emitting display apparatus described above, at least some of the elements thereof may be formed by using the deposition apparatus or the method of manufacturing an organic light-emitting display apparatus, according to the above-described embodiments of the present invention.

For example, an intermediate layer may be formed by using the deposition apparatus or the method of manufacturing an organic light-emitting display apparatus according to the above-described embodiments of the present invention. For example, along with a light emission layer (EML) of the intermediate layer, a hole injection layer (HIL), a hole transport layer (HTL), an electron transport layer (ETL), and/or an electron injection layer (EIL), included in the intermediate layer, may be formed by utilizing the deposition apparatus or the method of manufacturing an organic light-emitting display apparatus according to the above-described embodiments of the present invention.

That is, when forming each layer of the intermediate layer 62, a deposition assembly including a deposition source, a deposition source nozzle unit, and a patterning slit sheet may be separated from a substrate, on which deposition is to be performed, that is, a substrate in which up to the pixel electrode 61 is formed, and deposition may be performed while one of the deposition assembly and the substrate moves relatively with respect to the other.

If the patterning slit sheet 130 includes a plurality of patterning slits 131 that are arranged along the X-axis direction, as illustrated in FIG. 3, and when a layer of the intermediate layer 62 is formed by using the patterning slit sheet 130, the corresponding layer may have a linear pattern. The layer may be, for example, a light emission (emissive) layer (EML).

As described above, the deposition apparatus illustrated in FIG. 1 allows accurate deposition on a portion set for the deposition in advance when depositing a large surface substrate, and thus, the intermediate layer 62 may be accurately formed even in an organic light-emitting display apparatus having a substrate of a size of 40 inches or greater, thereby enabling manufacture of a high-quality organic light-emitting display apparatus.

As described above, according to the embodiments of the present invention, provided are a method of manufacturing an organic light-emitting display apparatus, a deposition apparatus using the method in which effluence (pollution) of a substrate that is being deposited is blocked or prevented during transportation of a transport unit and maintenance of the organic light-emitting display apparatus is easy, and an organic light-emitting display apparatus manufactured by using the method. However, the scope of the present invention is not limited by the effect of the present invention.

While the present invention has been particularly shown and described with reference to exemplary embodiments thereof, it will be understood by those of ordinary skill in the art that various changes in form and details may be made therein without departing from the spirit and scope of the present invention as defined by the following claims, and equivalents thereof.

What is claimed is:

1. A method of manufacturing an organic light-emitting display apparatus, the method comprising:
detachably fixing a substrate on a surface of a transfer unit at a first flip transport unit;
locating the surface of the transfer unit, to which the substrate is fixed, within a first plane, by rotating the first flip transport unit in a second rotational direction by 180 degrees;
transporting the transfer unit from the first flip transport unit to a first transport unit;
forming a layer by depositing a deposition material emitted from a deposition assembly, on the substrate while placing the deposition assembly and the substrate to be separated from each other by a set distance and moving the substrate relatively with respect to the deposition assembly in a first direction via the first transport unit;
transporting the transfer unit from the first transport unit to a second flip transport unit;
rotating the second flip transport unit in a first rotational direction opposite to the second rotational direction by 180 degrees while the transfer unit, on which the substrate is fixed, is disposed on the second flip transport unit;
separating and discharging the substrate from the transfer unit;
locating the surface of the transfer unit, to which the substrate is fixed, within a second plane, by rotating the second flip transport unit in the second rotational direction by a first angle, while the transfer unit, from which the substrate is separated, is located on the second flip transport unit;
transporting the transfer unit from the second flip transport unit to the second transport unit;
transporting the transfer unit to the first flip transport unit in the opposite direction to the first direction via a second transport unit; and
rotating the first flip transport unit in the first rotational direction by the first angle while the transfer unit is disposed on the first flip transport unit.

2. The method of claim 1, wherein when rotating the first flip transport unit or the second flip transport unit, the first flip transport unit or the second flip transport unit is rotated with respect to an axis that is parallel to an axis defined by a portion where the first plane and the second plane cross each other.

3. The method of claim 1, wherein the first plane and the second plane cross each other perpendicularly.

4. The method of claim 1, wherein the first angle is 90 degrees.

5. The method of claim 1, wherein the locating the surface of the transfer unit, to which the substrate is fixed, within the first plane, by rotating the first flip transport unit in the second rotational direction by 180 degrees comprises locating first flip guide rails of the first flip transport unit along the same line as first guide rails of the first transport unit.

6. The method of claim 1, wherein the locating the surface of the transfer unit, to which the substrate is fixed, within the second plane, by rotating the second flip transport unit by the first angle, comprises locating second flip guide rails of the second flip transport unit along the same line as second guide rails of the second transport unit.

7. A method of manufacturing an organic light-emitting display apparatus, the method comprising:
detachably fixing a substrate on a surface of a transfer unit at a first flip transport unit;
locating the surface of the transfer unit, to which the substrate is fixed, within a first plane, by rotating the first flip transport unit in a second rotational direction by 180 degrees;
transporting the transfer unit from the first flip transport unit to a first transport unit;
forming a layer by depositing a deposition material emitted from a deposition assembly, on the substrate while placing the deposition assembly and the substrate to be separated from each other by a set distance and moving the substrate relatively with respect to the deposition assembly in a first direction via the first transport unit;
transporting the transfer unit from the first transport unit to a second flip transport unit;
rotating the second flip transport unit in a first rotational direction opposite to the second rotational direction by 180 degrees while the transfer unit, on which the substrate is fixed, is disposed on the second flip transport unit;
separating and discharging the substrate from the transfer unit;
locating the surface of the transfer unit, to which the substrate is fixed, within a second plane, by rotating the second flip transport unit in the first rotational direction by a first angle, while the transfer unit, from which the substrate is separated, is located on the second flip transport unit;
transporting the transfer unit from the second flip transport unit to the second transport unit;
transporting the transfer unit to the first flip transport unit in the opposite direction to the first direction via the second transport unit; and
rotating the first flip transport unit in the second rotational direction by the first angle while the transfer unit is disposed on the first flip transport unit.

8. The method of claim 7, wherein when rotating the first flip transport unit or the second flip transport unit, the first flip transport unit or the second flip transport unit is rotated with respect to an axis that is parallel to an axis defined by a portion where the first plane and the second plane cross each other.

9. The method of claim 7, wherein the first plane and the second plane cross each other perpendicularly.

10. The method of claim 7, wherein the first angle is 90 degrees.

11. The method of claim 7, wherein the locating the surface of the transfer unit, to which the substrate is fixed, within the first plane, by rotating the first flip transport unit in the second rotational direction by 180 degrees comprises locating first flip guide rails of the first flip transport unit along the same line as first guide rails of the first transport unit.

12. The method of claim 7, wherein the locating the surface of the transfer unit, to which the substrate is fixed, within the second plane, by rotating the second flip transport unit by the first angle, comprises locating second flip guide rails of the second flip transport unit along the same line as second guide rails of the second transport unit.

13. An organic light-emitting display apparatus comprising:
a substrate;
a plurality of thin film transistors on the substrate;
a plurality of pixel electrodes electrically connected to the plurality of thin film transistors;
a plurality of deposition layers on the plurality of pixel electrodes; and
an opposite electrode on the plurality of deposition layers,
wherein at least one of the deposition layers is a linear pattern formed by utilizing the method of claim 1.

14. An organic light-emitting display apparatus comprising:
a substrate;
a plurality of thin film transistors on the substrate;
a plurality of pixel electrodes electrically connected to the plurality of thin film transistors;
a plurality of deposition layers on the plurality of pixel electrodes; and
an opposite electrode on the plurality of deposition layers,
wherein at least one of the deposition layers is a linear pattern formed by utilizing the method of claim 7.
